(19) United States
(12) Patent Application Publication
(10) Pub. No.: US 2007/0113888 A1
(43) Pub. Date: May 24, 2007

(54) Method for treating powder particles

(75) Inventors: Volker Geyer, Niederkruechten (DE); Marit Kauk, Harku (EE); Jaan Raudoja, Tallinn (EE); Tiit Varema, Tallinn (EE); Mare Altosaar, Tallinn (EE)

Correspondence Address: MARSHALL, GERSTEIN & BORUN LLP, 233 S. WACKER DRIVE, SUITE 6300, SEARS TOWER, CHICAGO, IL, 60606, US

(73) Assignee: SCHEUTEN GLASGROEP, VENLO (NL)

(21) Appl. No.: 10/582,571

(22) PCT Filed: Dec. 14, 2004
(86) PCT No.: PCT/EP04/14232

§ 371 Date: Jun. 12, 2006

(30) Foreign Application Priority Data
Dec. 22, 2003 (EP) 03029577.8

(51) Int. Cl. C01B 19/00; H01L 31/00

(52) U.S. Cl. 136/262; 423/508; 136/264

(57) ABSTRACT

A method for treating powder particles of a Cu(In,Ga)Se₂, compound, according to which the powder particles and a quantity of sulfur are introduced into a vessel and heated and maintained at a constant temperature over a period of time. The invention also relates to a monograin-membrane solar cell containing a rear contact, a monogram membrane containing powder particles that have been treated according to the inventive method, at least one semiconductor layer and a front contact.

The invention relates to a method for treating powder particles.

The method is especially well-suited for treating powder particles consisting of a Cu(In,Ga)Se₂ compound.

These powders are suitable for the production of mono-particle membranes that are used in solar cells.

The invention is based on the objective of creating a method with which the properties of a Cu(In,Ga)Se₂ powder can be improved with an eye towards the use of this powder in a solar cell.

It is also the objective of the invention to create a mono-particle membrane solar cell with the highest possible efficiency factor.

In terms of the method, this objective is achieved according to the invention by a method for treating powder particles consisting of a Cu(In,Ga)Se₂ compound, in which method the powder particles and sulfur are placed into a vessel and the vessel contents consisting of the powder particles and the sulfur are heated up and kept at a constant temperature after having been heated up.

The use of the method according to the invention leads to the surprising effect that solar cells in which the powder treated by means of the method are used have a much higher efficiency factor than solar cells in which a powder is used that was not treated by means of the method according to the invention.

A possible explanation for the marked improvement of the photovoltaic properties of the powder particles could be the following:

The possibility exists that regions with a sub-stoichiometric content of Se might exist in the particles consisting of the Cu(In,Ga)Se₂ compound. In these regions, a deposition of a foreign phase consisting of Cu, Ga or In can occur from a phase consisting of stoichiometric Cu(In,Ga)Se₂, whereby the foreign phases tend to be deposited on the surface of the powder particles.

Due to the metallic nature of the foreign phase, for example, a short circuit can occur in the p-n contact of the solar cell.

With the method according to the invention, a sulfurization was carried out during which the foreign phases present on the surface of the powder particles are presumably converted into Cu(In,Ga)S₂, a compound that is likewise employed in solar cells.

This explanation is supported by the fact that a markedly elevated open-circuit voltage was measured in solar cells in which the powder treated according to the invention was employed.

In a preferred implementation of the method, the powder particles are filled into a two-zone ampoule, whereby the powder particles are placed into one of the zones and the sulfur is placed into the other zone.

The powder particles are then heated up, preferably to a temperature between 400° C. and 600° C. [752° F. and 1112° F.].

The sulfur is preferably heated up to a temperature of about 100° C. [212° F.].

The powder particles and the sulfur are kept at the appertaining temperature for a period of time between one hour and 50 hours.

In a likewise preferred implementation of the method, a mixture consisting of powder particles and sulfur is filled into an ampoule.

The mixture is then heated to a temperature between 300° C. and 600° C. [572° F. and 1112° F.] and kept at this temperature for a period of time between 5 minutes and 4 hours. An especially advantageous temperature range lies between 380° C. and 410° C. [716° F. and 770° F.].

Within the scope of the invention, an advantageous mono-particle membrane solar cell was likewise created that is characterized by an especially high efficiency factor in comparison to other mono-particle membrane solar cells.

The solar cell comprises a back contact, a mono-particle membrane, at least one semiconductor layer and a front contact, and it is characterized in that the mono-particle membrane contains the powder particles treated according to the invention.

Due to the advantageous properties of the particles treated according to the invention, this solar cell exhibits a high efficiency factor.

The preferred implementations of the method according to the invention will be explained in detail below:

In an implementation of the method, the powder particles consisting of a Cu(In,Ga)Se₂ compound and the sulfur are filled into a so-called two-zone ampoule, whereby the powder particles are placed into one of the zones and the sulfur is placed into the other zone of the two-zone ampoule.

A two-zone ampoule consists of a tube that is closed or can be closed at both ends and that is constricted in the middle. The shape of the ampoule is thus like that of an hourglass. The two-zone ampoule is used lying horizontally with this method and should be made of a material that does not react with the substances that are filled into it. Thus, it is made, for example, of quartz glass.

A typical filling quantity consists of 10 grams of powder particles and 2 grams of sulfur.

The two-zone ampoule is evacuated and the sulfur present in the one zone is heated to a temperature of about 100° C. [212° F.]. This results in the formation of gaseous S₂ that spreads through the entire ampoule.

The powder particles present in the other zone of the two-zone ampoule are heated to a temperature between 400° C. and 600° C. [752° F. and 1112° F.].

The sulfur vapor pressure in the zone of the ampoule containing the powder particles can be varied by changing the temperature that prevails in this zone. It should be between 0.13 Pa and 133 Pa.

The powder particles and the sulfur are now kept at the appertaining temperature for a period of time between one hour and 50 hours. During this period of time, as explained above, the foreign phases consisting of Cu, In or Ga that might be present on the surface of the powder particles are presumably converted into a Cu(In,Ga)S₂ compound.

At the end of the period of time, the ampoule is cooled off and the sulfurized powder particles can be removed.

Especially good results were obtained in terms of improving the photovoltaic properties of the powder particles by means of a treatment in which the powder particles were heated to 530° C. [986° F.] and the sulfur was heated to 107° C. [224.6° F.]. At these temperatures, a sulfur vapor pressure of 1.33 Pa was established in the zone of the two-zone ampoule containing the powder particles. The treatment time was 18 hours.

In another implementation of the method, a mixture consisting of the powder particles and the sulfur is filled into an ampoule which is once again made of quartz glass. A typical mixture consists of 50 vol.-% powder and 50 vol.-% sulfur.

The ampoule is evacuated and the mixture is heated to a temperature between 300° C. and 600° C. [572° F. and 1112° F.], preferably to a temperature between 380° C. and 410° C. [716° F. and 770° F.]. At this temperature, the sulfur is liquid and uniformly surrounds the powder particles which, at this temperature, are present in the solid phase. Thus, the powder particles are “boiled” in the liquid sulfur in a manner of speaking.

With this implementation, the period of time during which the mixture is kept at the established temperature after the heating step is between 5 minutes and 4 hours.

During this period of time, the foreign phases consisting of Cu, In or Ga that might be present on the surface of the particles are presumably once again converted into a Cu(In,Ga)S₂ compound.

Especially good results in terms of improving the photovoltaic properties of the particles were obtained by means of a 5-minute treatment at 410° C. [770° F.] and a subsequent 30-minute treatment at 380° C. [716° F.].

On the basis of the drawings, a few analyses will now be presented that were carried out for solar cells that made use of a powder consisting of a CuInSe₂ compound that had been treated by means of the method according to the invention.

The figures show the following:

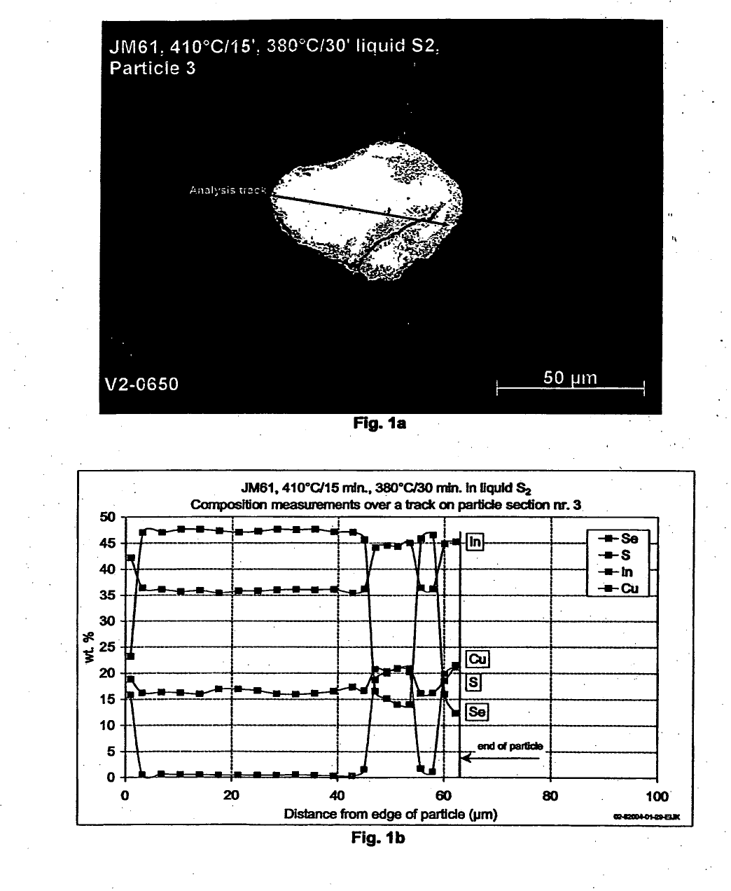

FIG. 1a—an image of a first powder particle with the analysis track drawn in,

FIG. 1b—a graph showing the chemical composition of the first powder particle along the analysis track,

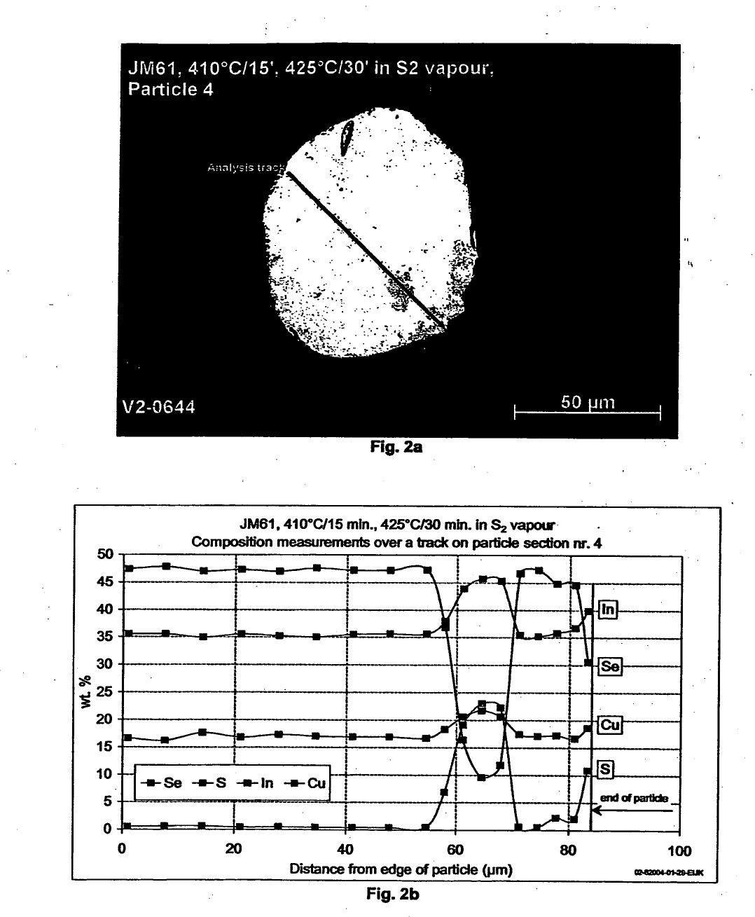

FIG. 2a—an image of a second powder particle with the analysis track drawn in,

FIG. 2b—a graph showing the chemical composition of the second powder particle along the analysis track,

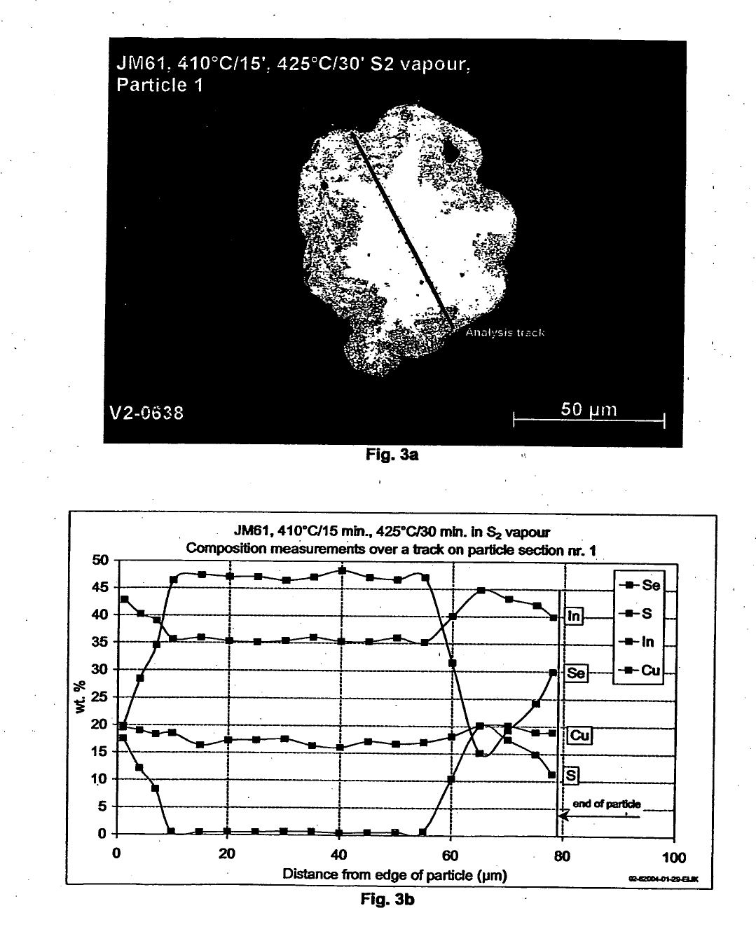

FIG. 3a—an image of a third powder particle with the analysis track drawn in,

FIG. 3b—a graph showing the chemical composition of a third powder particle with the analysis track drawn in,

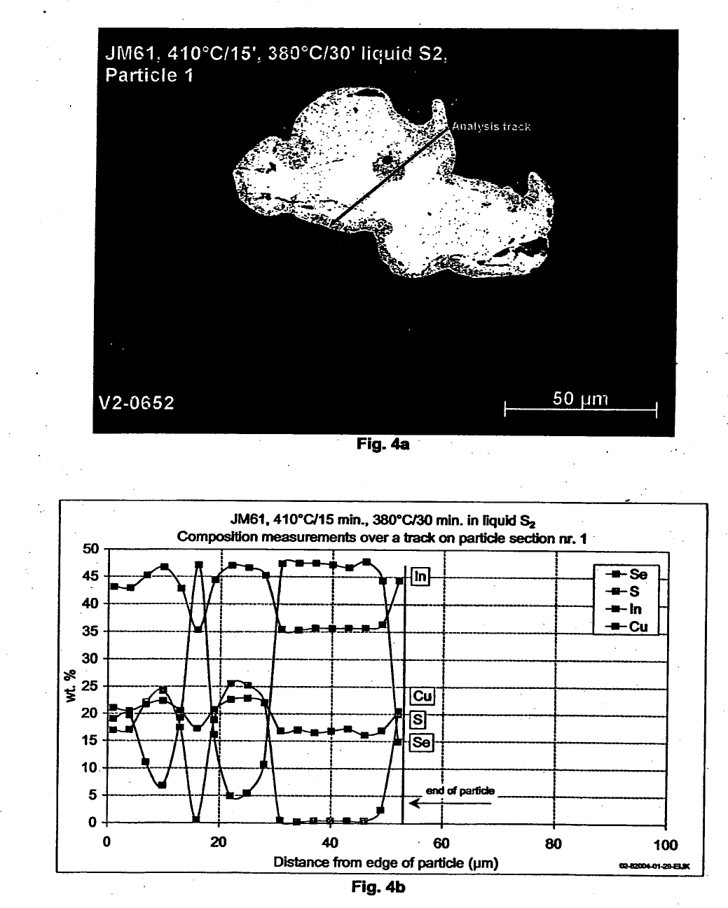

FIG. 4a—an image of a fourth powder particle with the analysis track drawn in,

FIG. 4b—a graph showing the chemical composition of the fourth powder particle along the analysis track,

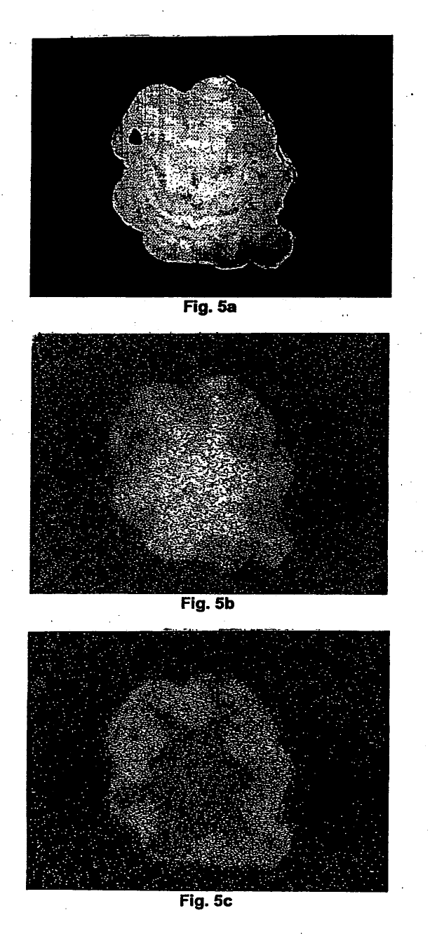

FIG. 5a—an image of a fifth powder particle,

FIG. 5b—an analysis of the Se content of the fifth powder particle,

FIG. 5c—an analysis of the S content of the fifth powder particle,

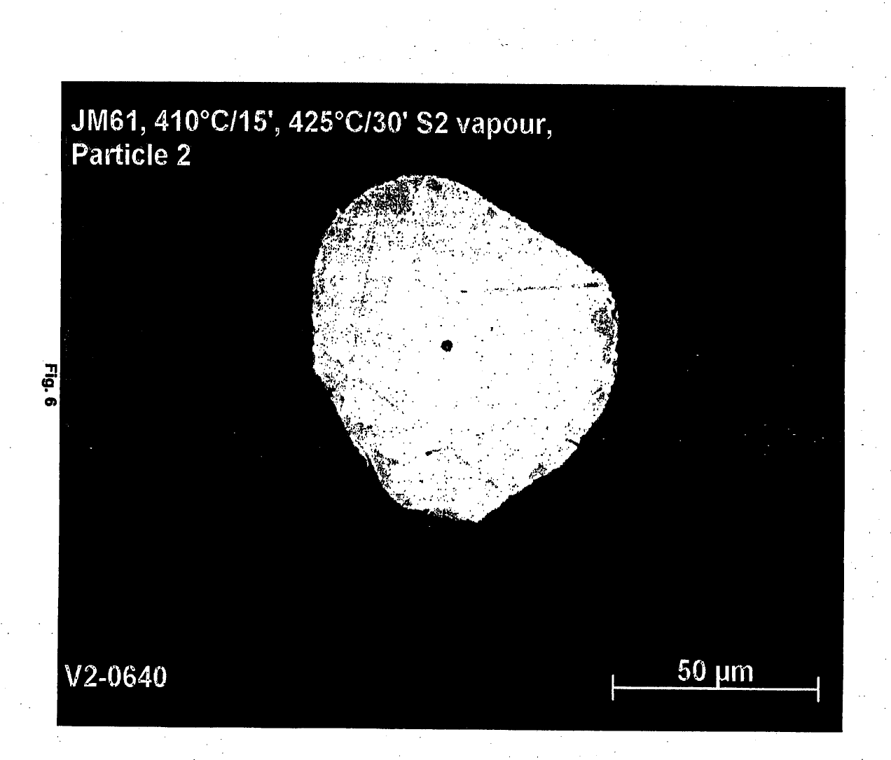

FIG. 6—an image of another powder particle,

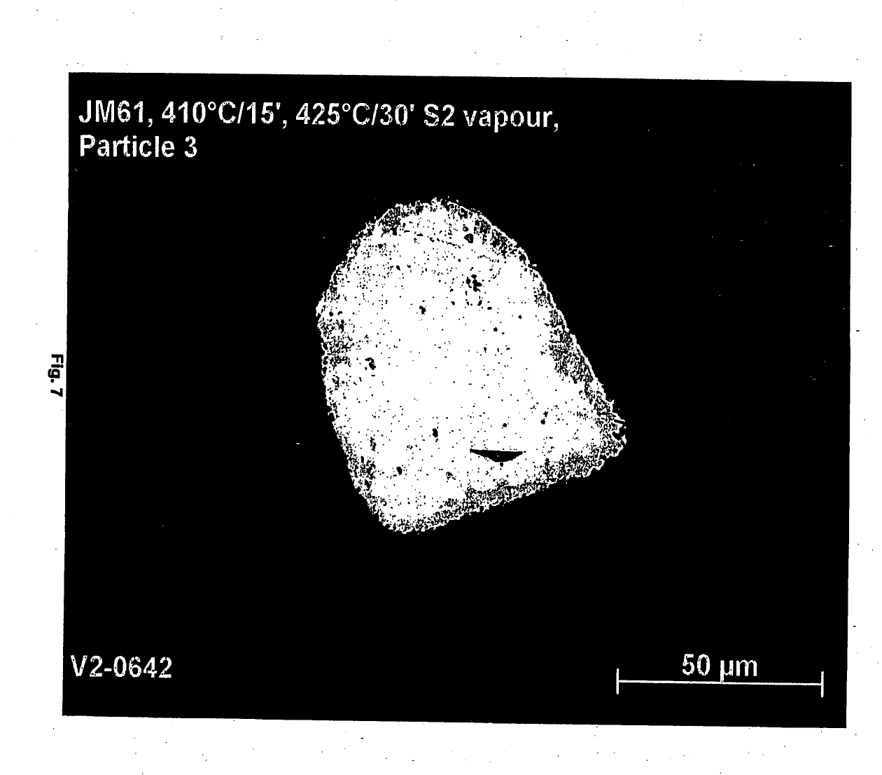

FIG. 7—an image of another powder particle,

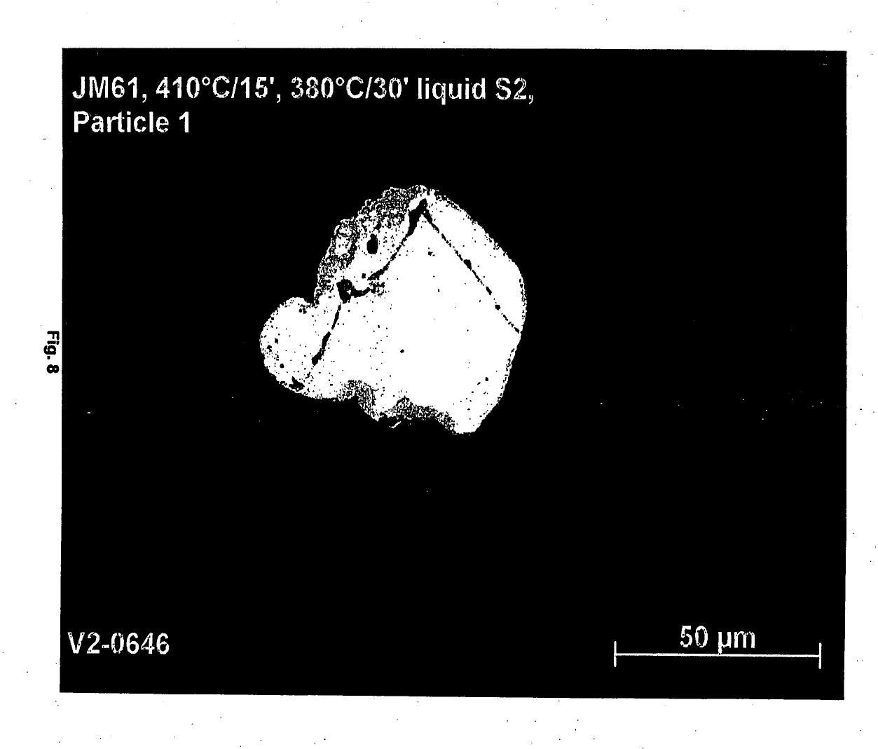

FIG. 8—an image of another powder particle,

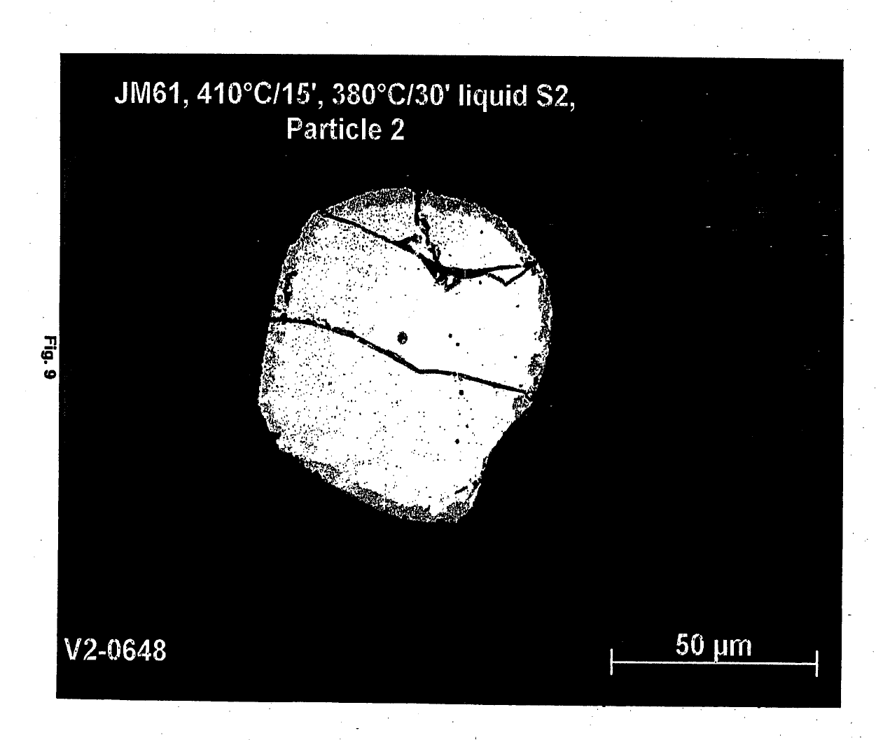

FIG. 9—an image of another powder particle,

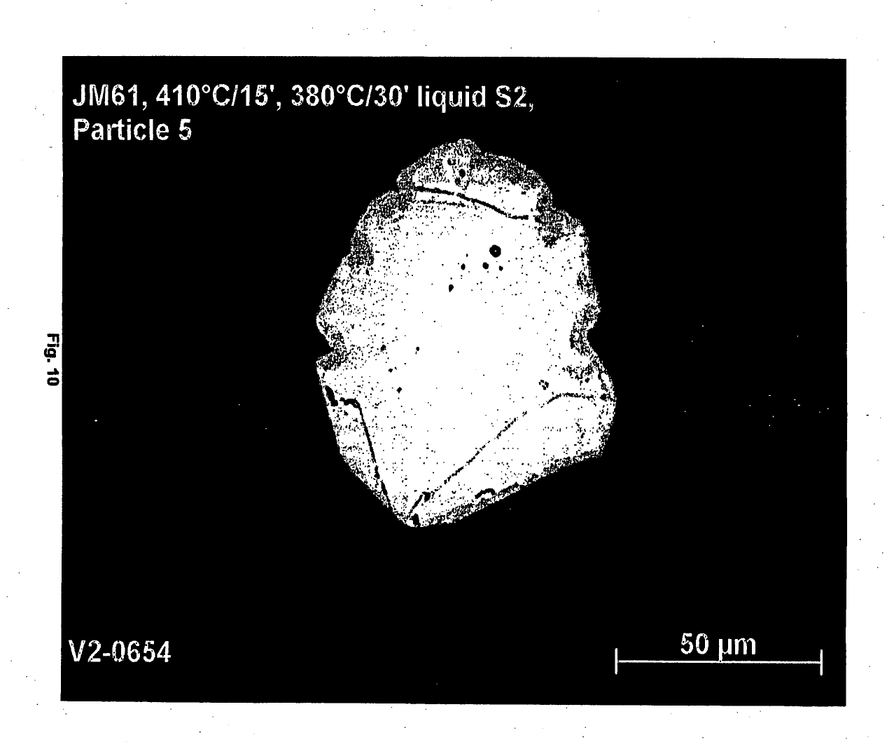

FIG. 10—an image of another powder particle,

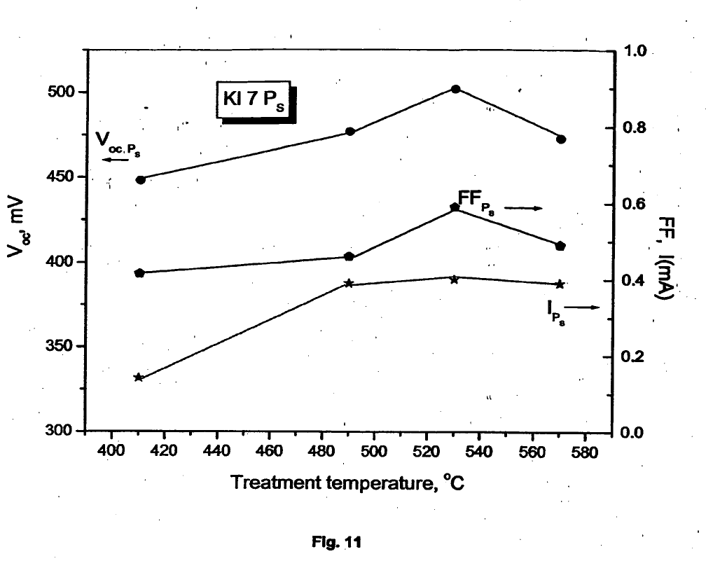

FIG. 11—a graph showing the value of a number of characteristic values of a solar cell as a function of the treatment temperature, and

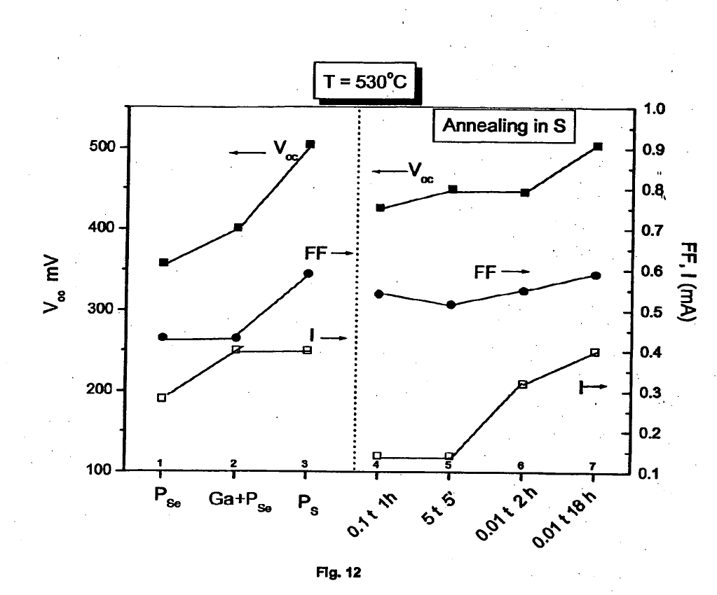

FIG. 12—a graph showing the value of a number of characteristic values of a solar cell as a function of the treatment duration.

The analysis was carried out with powder particles that consisted of a CuInSe₂ compound prior to the treatment and thus did not contain any Ga.

FIG. 1a shows the light-microscopic image of such a powder particle that was “boiled” for 15 minutes at 410° C. [770° F.] (410° C., 15′) and subsequently for 30 minutes at 380° C. [716° F.] (380° C., 30′) in liquid S₂. An analysis track is likewise drawn in the figure.

The chemical composition along this analysis track was examined. The results of this examination are shown in FIG. 1b on the basis of a graph. The horizontal axis indicates the distance from the edge of the powder particle at which the analysis was performed and the vertical axis indicates the percentage by weight (wt. %) in which an element is present at that place in the powder particle.

In FIG. 1b, it can be seen that, up to a distance of about 55 μm from the edge of the powder particle, the chemical composition of the powder particle corresponds approximately to the composition of stoichiometric CuInSe₂. This has about 18.8% by weight of Cu, about 34.2% by weight of In and approximately 47% by weight of Se. Sulfur is hardly present.

It can also be seen in FIG. 1b that, beyond a distance of about 55 μm from the edge of the powder particle and up to a distance of about 70 μm, especially the Se content markedly decreases and increases again, and the S content increases and decreases again.

This fact supports the already formulated assumption that, at this place in the analysis track that appears dark in the image of FIG. 1a, a CuInSe₂ compound with a sub-stoichiometric fraction of Se is present, and that here, during the treatment of the powder particle by means of the method according to the invention, the Cu and In fraction that is in excess relative to the stoichiometric amount was converted with the sulfur into CuInS₂. At the preceding places in the analysis track, such a conversion apparently did not take place.

It can be concluded that, at the places where a sub-stoichiometric fraction of Se was present before the treatment of the particles, after the treatment by means of the method according to the invention, CuInSe₂ in a virtually stoichiometric composition as well as CuInS₂ are present.

FIGS. 2a to 4b show similar results for other powder particles. The figures each show the temperature at which and the period of time during which the powder particles were treated. It is likewise explained whether the powder particles were “boiled” in liquid sulfur (“liquid S₂”) or whether the particles were treated with gaseous sulfur (“S₂ vapor”) in the two-zone ampoule.

FIG. 5b shows the result of an Se content analyzed with the method of backscattering electron imaging for the powder particle shown in FIG. 5a, which is likewise an electron microscopic image. The bright regions in FIG. 5b with a high density of white dots correspond to the regions with a high Se content while the regions correspond to places with a low Se content.

FIG. 5c shows the result of a backscattering electron image that is sensitive to the S content for the powder particle shown in the image in FIG. 5a. The bright regions in FIG. 5c correspond to regions with a high S content while the dark regions correspond to places with a low S content.

A comparison of FIGS. 5b and 5c shows that regions with a low Se content correspond to the regions with a high S content.

This fact likewise supports the hypothesis that was used to explain the results in FIGS. 1a to 4b.

FIGS. 6 to 10 show additional light-microscopic images of polished powder particles.

FIGS. 11 and 12 show the characteristic values of solar cells in which the particles treated according to the invention were used as a function of various parameters of the treatment.

The solar cells preferably comprise a back contact, a mono-particle membrane, at least one semiconductor layer and a front contact.

In order to produce the solar cells, the particles are first embedded in a mono-particle membrane, preferably configured as a polymer membrane, that was applied onto the back contact of the solar cell.

The back contact consists of an electrically conductive adhesive that is applied onto a glass substrate.

At least another semiconductor layer is applied onto the mono-particle membrane consisting of the particles embedded in the polymer membrane. The semiconductor layer is preferably a CdS buffer layer and a layer consisting of intrinsic ZnO.

Finally, a layer of an electrically conductive ZnO:Al alloy is applied onto the semiconductor layer. The electrically conductive ZnO:Al alloy layer serves as the front contact of the solar cell.

FIG. 11 shows the open-circuit voltage V_{OC}, the filling factor FF and the short-circuit current I of a solar cell containing the particles treated according to the invention, as a function of the treatment temperature. The index P_{S} here indicates that the particles underwent a sulfurization according to the invention.

The results shown in FIG. 11 relate to a sulfurization carried out in a two-zone ampoule at a certain fixed temperature of the sulfur.

The power irradiated into the solar cell during the series of measurements was likewise set at a specific fixed value. Filled-in rectangles, circles and empty rectangles indicate the actual measuring points here as well as in FIG. 12.

The shown measured results and especially the curve that indicates the dependence of the open-circuit voltage V_{OC} confirm the assertion made above that especially good results in terms of improving the photovoltaic properties of the powder particles were obtained by means of a treatment in which the powder particles were heated to a temperature of 530° C. [986° F].

FIG. 12 shows the dependence of the characteristic values on the other parameters of the treatment. The results likewise relate to the treatment in the two-zone ampoule and were recorded for powder particles that were heated to a temperature of 530° C. [986° F.] for the treatment.

In addition to the sulfurization according to the invention, other methods of treating the powder particles were also tested. The results of these alternative methods are shown on the left-hand side of FIG. 12.

The particles underwent the treatment according to the invention with sulfur (P_{S}) as well as an analogous treatment in which the sulfur was replaced by selenium (P_{Se}). Moreover, the treatment with selenium was also carried out for powder particles that did not consist of a pure CuInSe₂ compound but rather that contained an admixture of Ga (Ga+P_{Se}). In accordance with the interpretation of the outcomes of the sulfurization according to the invention, a conversion of the foreign phases into Cu(In,Ga)Se₂ is to be expected with the two latter treatment methods.

The dependence of the open-circuit voltage V_{OC}, the filling factor FF and the short-circuit current I on the treatment method depicted in FIG. 12 shows that the treatment according to the invention yields the best properties for the particles.

Consequently, the conversion of the foreign phases into Cu(In,Ga)S₂ seems to function much better than the conversion of the foreign phases into Cu(In,Ga)Se₂.

The right-hand side of the diagram in FIG. 12 shows the dependence of the characteristic values for a sulfurization (annealing in S) on the duration of the treatment and on the sulfur vapor pressure set in the zone of the two-zone ampoule containing the powder particles. The temperature in the zone containing the powder particles was 530° C. [986° F.] and the sulfur vapor pressure was varied exclusively by changing the temperature that prevailed in the zone containing the sulfur.

The power irradiated into the solar cell was kept at a constant value for the measurements, as was also illustrated for the measurement of the results shown in the left-hand part of FIG. 12.

Here, the measuring points refer to measurements on solar cells in which powder particles were used that underwent a treatment for 1 hour (1 h), 5 minutes (5′), 2 hours (2 h) and 18 hours (18 h) at a sulfur vapor pressure of 13.33 Pa (0.1 t), 666.5 Pa (5 t) and 1.33 Pa (0.01 t).

The results and especially the curve for the open-circuit voltage V_{OC} confirm the assertion made above that especially good results in terms of improving the photo-voltaic properties of the powder particles were obtained by means of a treatment in which the sulfur vapor pressure was 1.33 Pa and the treatment duration was 18 hours.

Up until now, this description has dealt exclusively with the treatment of the powder particles. An especially preferred method for the production of the powder particles consisting of a Cu(In,Ga)Se₂ compound will be presented below:

First of all, in this preferred method, Cu and In and/or Cu and Ga are alloyed, whereby the molar amounts of Cu employed on the one hand and of In and Ga on the other hand are selected in such a way as to form CuIn and CuGa alloys having low contents of Cu. It has proven to be especially advantageous in the production of powder particles employed in solar cells for the Cu:(In+Ga) ratio, that is to say, the ratio of the molar amount of Cu employed to the sum of the molar amount of In employed and the molar amount of Ga employed, to lie between 1 and 1:1.2.

The ratio of the molar amount of Ga employed to the molar amount of In employed is preferably between 0 and 0.43. In this context, a ratio of 0.43 corresponds approximately to a Ga fraction of 30% relative to the molar amount of In and Ga. Thus, with the method, preferably those Cu(In,Ga)Se₂ compounds are produced whose molar ratio of Ga to In lies between this molar ratio of the compounds CuInSe₂ and CuGa_{0.3}In_{0.7}Se₂.

The alloys are then ground up into a powder, whereby it has been found that the particle sizes of the Cu(In,Ga)Se₂ powder particles to be produced depend on the particle size of the powder made from the CuIn and/or CuGa alloy. Hence, powders are ground systematically so as to contain particles of a specific size.

The powder consisting of the alloys CuIn and CuGa is now filled into an ampoule that is made of a material that does not react with any of the substances that are to be placed into it. Thus, it is made, for example, of quartz glass.

Se is added to the powder in an amount that corresponds to the stoichiometric fraction of this element in the Cu(In,Ga)Se₂ compound that is to be produced.

Furthermore, either Kl or NaI is added as the fluxing agent, whereby the fraction of the fluxing agent in the melt that is subsequently formed is typically about 40 vol.-%. In general, however, the fraction of the fluxing agent in the melt can be between 10 vol.-% and 90 vol.-%.

The ampoule is now evacuated and heated with the indicated content to a temperature between 650° C. and 810° C. [1202° F. and 1490° F.]. Cu(In,Ga)Se₂ is formed during the heating process.

Once a temperature within the above-mentioned temperature range is reached, Cu(In,Ga)Se₂ recrystallizes and, at the same time, the particles grow.

The fluxing agent will have melted at this temperature, so that the space between the particles is filled with a liquid phase that serves as a transport medium.

The melt is kept constant at the pre-set temperature during a certain holding time. Depending on the desired particle size, a holding time between 5 minutes and 100 hours can be required. Typically, this is about 30 hours.

The growth of the particles is interrupted by cooling off the melt. Here, it is very advantageous to quench the melt very rapidly, for example, within just a few seconds.

This so-called quenching seems to be necessary so that any binary CuSe phases that might have formed will remain in the fluxing agent.

If the cooling off is carried out slowly, the risk probably exists that the metallic CuSe phases will be deposited onto the Cu(In,Ga)Se₂ crystals, markedly impairing the properties of the produced powder in terms of its use in solar cells.

In a last step of the method, the fluxing agent is removed by dissolving it out with water. The mono-crystalline powder particles can then be taken out of the ampoule.

The suitable temperature course over time during the heating up and cooling off as well as the holding time and the temperature to be maintained during the holding time are determined in preliminary experiments.

Using the method described, powders can be produced whose individual particles have a mean diameter of 0.1 μm to 0.1 mm. The particle size distribution within the powder corresponds to a Gauss distribution along the lines of D=A·t^{1/n}·exp(−E/kT), wherein D is the particle diameter, t is the holding time and T is the temperature of the melt; k, as usual, stands for the Boltzmann constant. The parameters A, n and E depend on the starting substances employed, on the fluxing agent and on the specific growth processes, which are not described in greater detail here. If Kl is used as the fluxing agent, then E equals approximately 0.25 eV. In this case, the value for n is between 3 and 4.

The mean particle size and the precise shape of the particle size distribution depend on the holding time, on the temperature of the melt and on the particle size of the employed powder consisting of the CuIn and CuGa alloys. Moreover, the mean particle size and particle size distribution are influenced by the choice of the fluxing agent.

The particles that can be produced with the method according to the invention are p-conductive and exhibit a very good electric conductivity. The electric resistances of the produced Cu(In,Ga)Se₂ powder particles were in a range from 100 Ω to 10 kΩ, depending on the Cu:Ga ratio selected, on the Cu:(In+Ga) ratio and on the temperature of the melt. This corresponds to a specific resistance of 10 kΩcm to 2 MΩcm.

By using the method, it was possible to produce mono-crystalline powders whose particles display a very uniform composition.

The powders are especially well-suited for the production of mono-particle membranes that are used in solar cells, whereby, using powders made with the method and treated by means of the method according to the invention, it was possible to make solar cells having a very high efficiency factor.

The production process presented seems to have the special advantage that, due to the addition of a sub-stoichiometric amount of Cu relative to the compound to be produced, primarily powder particles that have a low content of Cu are formed. This avoids the problem that a phase segregation into stoichiometric CuInSe₂ and into a metallic CuSe binary phase occurs in the particles. This foreign phase tends to accumulate on the surface of the particles and can cause short circuits in the solar cell.

Furthermore, the described production method apparently has the advantage that the CuSe phase that is formed during the production of the particles remains in the fluxing agent and is not deposited on the particles.

Especially in view of the possible application purposes of the powder produced with the method according to the invention, it should be pointed out that it is also fundamentally possible to add S, in addition to the Se, to the powder consisting of the CuIn and/or CuGa and to melt it together with the fluxing agent. By the same token, the Se can be completely replaced with S.

Consequently, the method makes it possible to produce a wide range of CuIn₁₋ₓGaₓS_{y}Se_{z}, compounds. These semiconductor compounds cover a range of band gap energies between 1.04 eV and 2.5 eV.

Thus, with the described production methods, powder particles can be produced that have very good photovoltaic properties that can be even further improved by the sulfur treatment according to the invention. The powder particles are especially well-suited for use in a solar cell.

1. A method for treating powder particles of a Cu(In,Ga)Se₂ compound,
comprising the steps of:
placing the powder particles and sulfur into a vessel, and
heating the vessel contents comprising the powder particles and the sulfur and maintaining the vessel contents at a constant temperature for a period of time sufficient to heat the particles.

2. The method according to claim 1,
comprising filling
the particles and the sulfur into a two-zone ampoule, placing the powder particles into one of the zones and placing the amount of sulfur into the other zone.

3. The method according to claim 1,
comprising heating
the particles to a temperature between 400° C. and 600° C. (752° F. and 1112° F.).

4. The method according to claim 1, comprising heating the sulfur to a temperature of about 100° C. (212° F.).

5. The method according to claim 1,
comprising maintaining
the particles and the sulfur at a constant temperature for a period of time between one hour and 50 hours.

6. The method according to claim 1,
comprising filling
a mixture of the powder particles and the sulfur into an ampoule.

7. The method according to claim 7,
comprising heating
the mixture to a temperature between 300° C. and 600° C. (572° F. and 1112° F.).

8. The method according to claim 7,
comprising maintaining
the mixture at a given temperature for a period of time between five minutes and four hours.

9. A mono-particle membrane solar cell comprising a back contact, a mono-particle membrane, at least one semiconductor layer and a front contact, wherein
the mono-particle membrane contains the powder particles treated according to claim 1.
